(19) United States
(12) Patent Application Publication
(10) Pub. No.: US 2024/0306334 A1
(43) Pub. Date: Sep. 12, 2024

(54) ELECTRONIC DEVICE

(71) Applicant: Sumitomo Wiring Systems, Ltd., Yokkaichi-shi, Mie (JP)

(72) Inventor: Toru TAKAHASHI, Yokkaichi-shi, Mie (JP)

(21) Appl. No.: 18/548,409

(22) PCT Filed: Feb. 18, 2022
(86) PCT No.: PCT/JP2022/006541

§ 371 Date: Aug. 30, 2023

(30) Foreign Application Priority Data
Mar. 9, 2021 (JP) 2021-037412

(51) Int. Cl. H05K 7/12; B60R 16/023; H02G 3/16

(52) U.S. Cl. CPC H05K 7/12; H02G 3/16; B60R 16/0239

(57) ABSTRACT

An electronic device includes: a circuit board 1 including a holder disposing surface and a connector disposing surface; a holder that holds capacitors; and a connector cover that is assembled on the holder and is disposed at a first end of the circuit board. The connector cover includes a holder engaging portion, which is disposed on the holder disposing surface of the circuit board and engages the holder, and temporary fixing portions disposed on the connector disposing surface of the circuit board. The holder includes a first frame that is disposed on the holder disposing surface of the circuit board and temporary locking portions that extend from the first frame and are disposed at a second end on an opposite side to the first end of the circuit board, wherein the temporary locking portions include temporary holding plates disposed on the connector disposing surface of the circuit board.

### CROSS-REFERENCE TO RELATED APPLICATIONS

This application is the U.S. national stage of PCT/JP2022/006541 filed on Feb. 18, 2022, which claims priority of Japanese Patent Application No. JP 2021-037412 filed on Mar. 9, 2021, the contents of which are incorporated herein.

### TECHNICAL FIELD

The technology disclosed by the present specification relates to an electronic device.

### BACKGROUND

A capacitor module equipped with a resin holder that holds a plurality of capacitors and a wiring board that is fixed to the holder is known as one example of a backup power supply mounted in a vehicle to supply backup power. The holder is provided with two board locking hooks for fixing to the wiring board. These board locking hooks engage through-holes provided in the wiring board (see JP 2016-27670A).

With the above configuration, when the board locking hooks are pressed into the through-holes, a component mounting area, where electronic components are mounted on the wiring board, becomes distorted by the pressing force, resulting in the risk of cracking or the like occurring at parts of the electronic components connected to the wiring board.

### SUMMARY

The electronic device disclosed in the present specification includes: a circuit board including a first surface and a second surface on an opposite side to the first surface; a holder for holding a power storage element; and a fixing member that is assembled on the holder and is disposed at a first end of the circuit board, wherein the fixing member includes a holder engaging portion, which is disposed on the first surface of the circuit board and engages the holder, and a temporary fixing portion, which is disposed on the second surface of the circuit board, and the holder includes a holder main body that is disposed on the first surface of the circuit board and a temporary locking portion that extends from the holder main body and is disposed at a second end on an opposite side to the first end of the circuit board, wherein the temporary locking portion includes a temporary holding portion disposed on the second surface of the circuit board.

### Advantageous Effects

According to the electronic device disclosed in the present specification, it is possible to temporarily fix a circuit board to a holder while avoiding the application of stress to the circuit board.

### BRIEF DESCRIPTION OF DRAWINGS

FIG. 1 is a perspective view of an electronic device according to an embodiment.

FIG. 2 is an exploded perspective view of the electronic device according to the embodiment.

FIG. 3 is a perspective view of a circuit board on which a connector is disposed.

FIG. 4 is a plan view of a state where the circuit board has been temporarily locked by a holder and a connector cover.

FIG. 5 is a cross-sectional view along a line A-A in FIG. 4.

FIG. 6 is a rear view of the connector cover.

FIG. 7 is a bottom view of the connector cover.

FIG. 8 is a perspective view of a first holder.

FIG. 9 is a perspective view of a second holder.

FIG. 10 is a perspective view of a first outer case.

FIG. 11 is a perspective view of a second outer case.

FIG. 12 is a plan view depicting a state where the circuit board has been assembled on the first holder.

FIG. 13 is a right side view depicting a state where the circuit board has been assembled on the first holder.

FIG. 14 is a left side view depicting a state where the circuit board has been assembled on the first holder.

FIG. 15 is a side view depicting a state where capacitors are held in the first holder.

FIG. 16 is a bottom view depicting the state where capacitors are held in the first holder.

FIG. 17 is a side view depicting a state where the second holder has been assembled on the first holder.

FIG. 18 is a side view depicting a state where the first outer case has been assembled on the circuit board and holder.

FIG. 19 is a plan view depicting the state where the first outer case has been assembled on the circuit board and holder.

FIG. 20 is a cross-sectional view taken along a line C-C in FIG. 19.

### DETAILED DESCRIPTION OF PREFERRED EMBODIMENTS

An electronic device disclosed by the present specification includes: a circuit board including a first surface and a second surface on an opposite side to the first surface; a holder for holding a power storage element; and a fixing member that is assembled on the holder and is disposed at a first end of the circuit board, wherein the fixing member includes a holder engaging portion, which is disposed on the first surface of the circuit board and engages the holder, and at least one temporary fixing portion, which is disposed on the second surface of the circuit board, and the holder includes a holder main body that is disposed on the first surface of the circuit board and at least one temporary locking portion that extends from the holder main body and is disposed at a second end on an opposite side to the first end of the circuit board, wherein each temporary locking portion includes a temporary holding portion disposed on the second surface of the circuit board.

According to the above configuration, during assembly of the electronic device, the second end of the circuit board is held between the holder main body and the temporary holding portion. After this, the holder is engaged by the holder engaging portion of the fixing member, and the first end of the circuit board is held between the holder engaging portion and the temporary fixing portion. With this configuration, it is easy to temporarily fix the circuit board to the holder while avoiding stress being applied to the circuit board.

In the electronic device according to (1), the circuit board may include at least one temporary locking recess that is disposed at the second end and receives the at least one temporary locking portion. With this configuration, it is possible to suppress positional displacements of the circuit board and the holder, which enables the assembly of the electronic device to be performed smoothly.

In the electronic device according to (2), the holder may include a plurality of the temporary locking portions of different widths and the circuit board may include a plurality of the temporary locking recesses for receiving the plurality of temporary locking portions, and one temporary locking recess out of the plurality of temporary locking recesses may have a width that is capable of receiving one of the temporary locking portions but is incapable of receiving another of the temporary locking portions.

With this configuration, a situation where the circuit board is fixed to the holder in the wrong orientation is avoided.

In the electronic device according to (1), (2), or (3) above, the circuit board may include a boss hole disposed at the first end, and the holder may include a boss that is inserted through the boss hole.

According to the above configuration, it is possible to suppress positional displacements between the first end of the circuit board and the holder from when the second end of the circuit board is held on the holder until the fixing member has been assembled, which makes it possible to smoothly assemble the electronic device.

The electronic device according to any one of (1) to (4) above may further include a connector attached to the circuit board, wherein the fixing member is a connector cover that covers at least part of the connector. With this configuration, the connector cover also serves to temporarily fix the circuit board, which can suppress an increase in the number of components.

In the electronic device according to (5) above, the connector cover may include two temporary fixing portions disposed on both sides of the connector. According to this configuration, it is possible to suppress positional displacements between the circuit board and the connector cover, which makes it possible to smoothly assemble the electronic device.

The electronic device according to any of (1) to (6) above, may further include an outer case for covering the circuit board and the holder, wherein the outer case may include a board fixing portion to which only the circuit board is fixed and a holder fixing portion to which only the holder is fixed.

According to this configuration, the circuit board and the holder are separately fixed to the outer case. With this configuration, the circuit board and the holder can be firmly fixed to the outer case, compared to a configuration where the circuit board and the holder are collectively fixed, which makes it possible to avoid a situation where a load is applied to connected parts of lead terminals of a power storage element and the circuit board.

Specific embodiments of the technology disclosed in the present specification will now be described with reference to the attached drawings. Note that the present disclosure is not limited to the illustrated configurations and is instead indicated by the range of the patent claims and intended to include all changes within the meaning and scope of the patent claims and their equivalents.

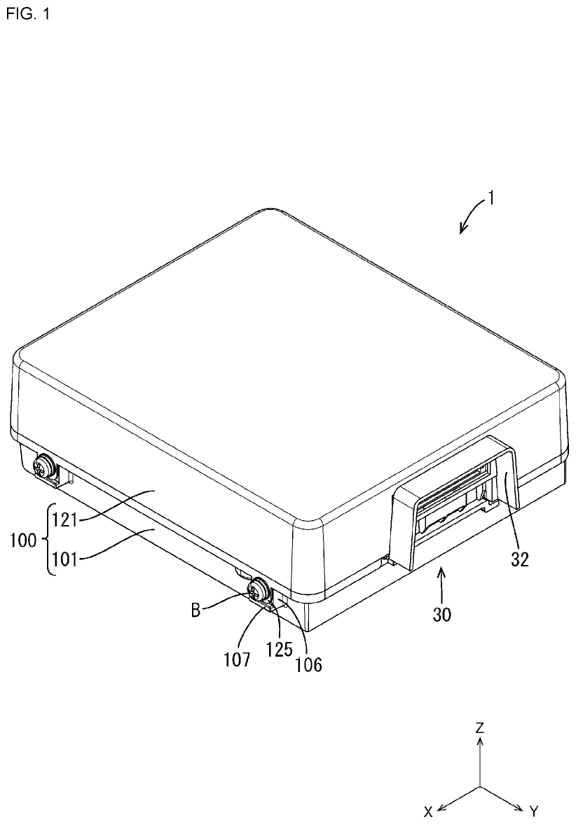

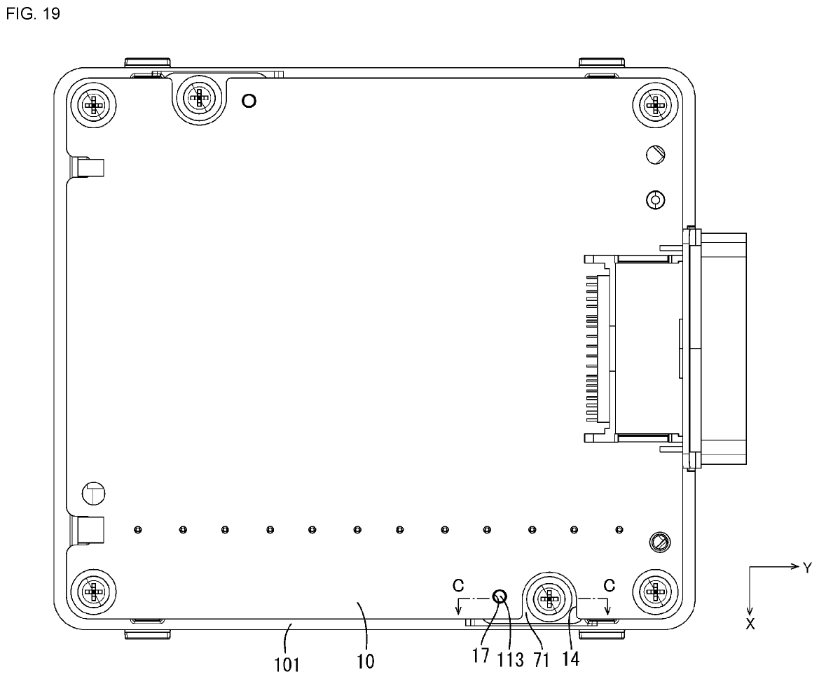

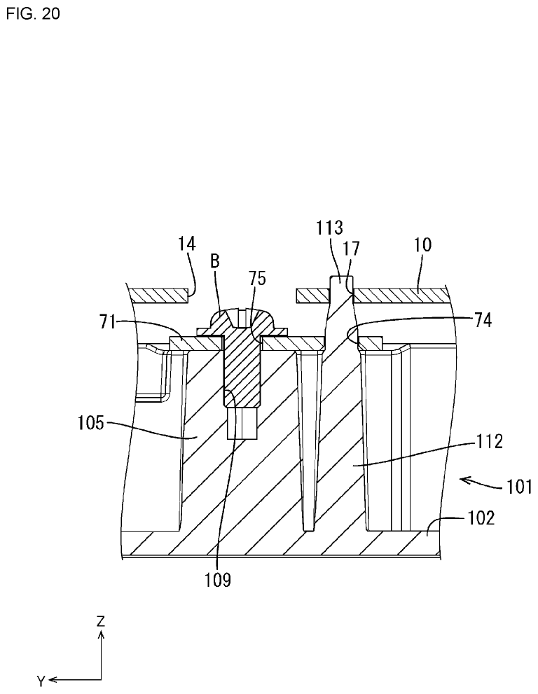

An embodiment will now be described with reference to FIGS. 1 to 20. An electronic device 1 according to the present embodiment is a backup power supplying apparatus included in a shift-by-wire (SBW) apparatus provided in a vehicle. When an abnormality has occurred, either for a power supply such as the battery installed in the vehicle or for wiring of a power supplying system or the like, that is, when a battery failure has occurred where the supplying of power from a battery is lost, backup power is supplied to the SBW-ECU (or “shift control unit”).

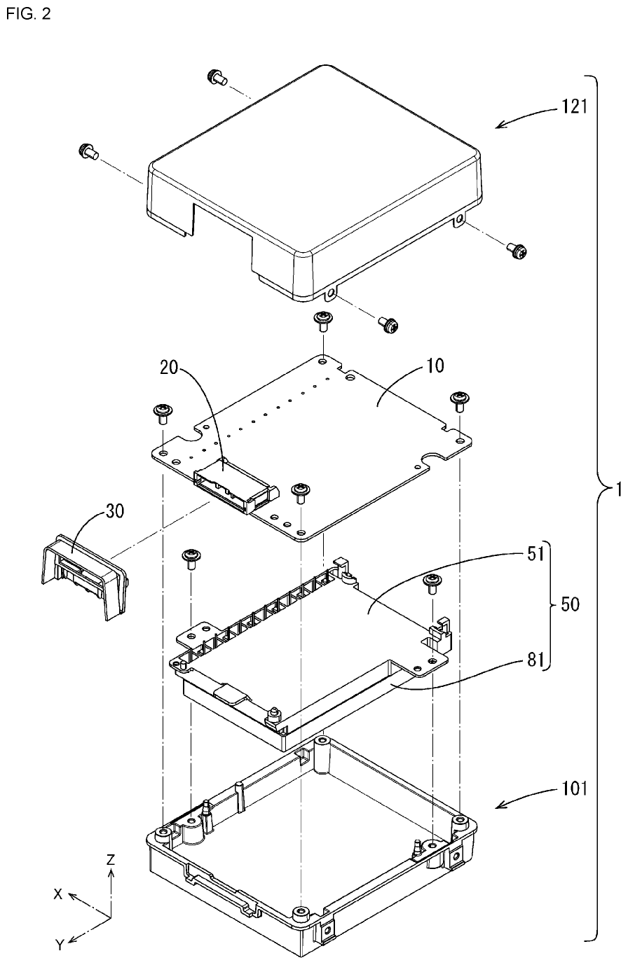

As depicted in FIGS. 1 and 2, the electronic device 1 includes a circuit board 10, a connector 20 fixed to the circuit board 10, a connector cover 30 (one example of a “fixing member”) that covers the connector 20, a holder 50 that is assembled on the circuit board 10 to hold capacitors 40 (one example of a “power storage element”), and an outer case 100 that internally houses the circuit board 10 and the holder 50.

### Circuit Board 10

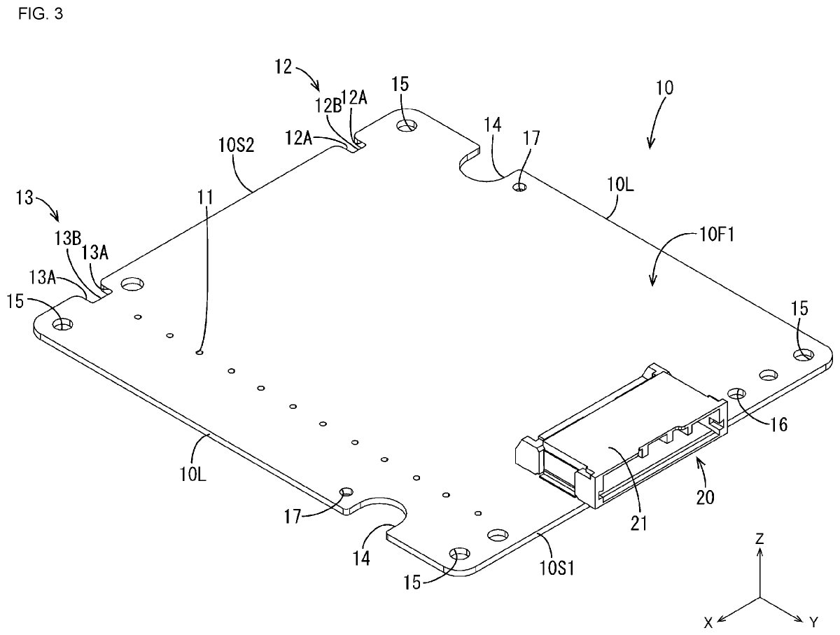

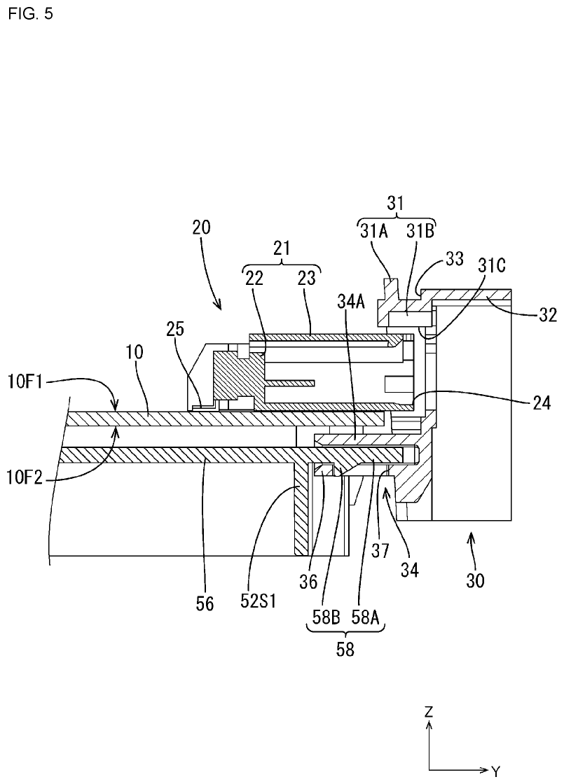

As depicted in FIGS. 3 and 5, the circuit board 10 is a printed circuit board of a known configuration where conductive paths are formed on one side or both sides of an insulating board by printed wiring technology. The circuit board 10 has the overall form of a rectangular plate, has a first short side 10S1, a second short side 10S2, and two long sides 10L, and further includes a connector disposing surface 10F1 and a holder disposing surface 10F2 on the opposite side to the connector disposing surface 10F1.

As depicted in FIG. 3, the circuit board 10 includes a plurality of through holes 11, a first temporary locking recess (or “temporary locking recess” or “one temporary locking recess”) 12, a second temporary locking recess 13 (another example of a “temporary locking recess”), two relief recesses 14, four first screw insertion holes 15, a first boss hole 16 (one example of a “boss hole”), and two second boss holes 17.

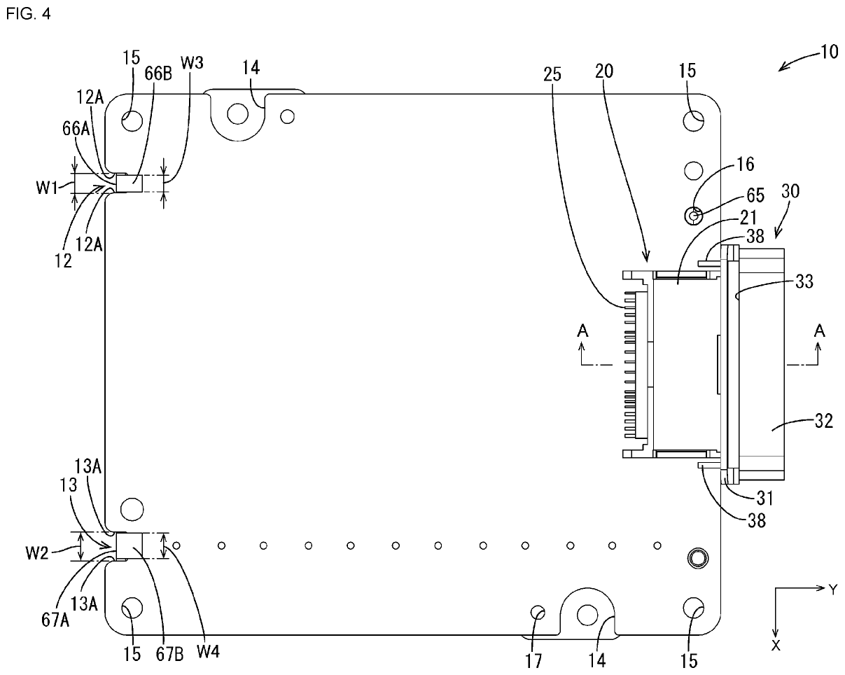

The first temporary locking recess 12 is a recess defined by two first side edges 12A, which are parallel and extend from the second short side 10S2 of the circuit board 10, and a first inner edge 12B that connects the two first side edges 12A. The second temporary locking recess 13 is a recess defined by two second side edges 13A, which are parallel and extend from the second short side 10S2 of the circuit board 10, and a second inner edge 13B that connects the two second side edges 13A. As depicted in FIG. 4, the width W1 of the first temporary locking recess 12 defined as the distance between the two first side edges 12A is smaller than the width W2 of the second temporary locking recess 13 defined as the distance between the two second side edges 13A.

Each of the relief recesses 14 is a recess that is inwardly recessed from one of the two long sides 10L of the circuit board 10. The four first screw insertion holes 15 are disposed in the four corners of the circuit board 10. The first boss hole 16 is disposed at a first end of the circuit board 10 adjacent to the first short side 10S1. The two second boss holes 17 are disposed adjacent to the two relief recesses 14.

### Connector 20

As depicted in FIGS. 3, 4, and 5, the connector 20 is disposed on the connector disposing surface 10F1 of the circuit board 10. The connector 20 includes a connector housing 21 that can mate with a mating connector, and a plurality of terminal fittings 25 that are assembled on the connector housing 21 and connected to the conductive paths on the circuit board 10.

The connector housing 21 is made of synthetic resin and is provided with a terminal holding wall 22 and a hood portion 23 that extends from the terminal holding wall 22.

As depicted in FIG. 5, the terminal holding wall 22 is a plate-like part of a certain thickness that holds the terminal fittings 25. The hood portion 23 is in the form of a rectangular tube that extends from the terminal holding wall 22 and includes an opening (or “mating hole 24”) on the opposite side to the terminal holding wall 22. The connector 20 is fixed in a state where a part thereof that is adjacent to the mating hole 24 protrudes outward from the first short side 10S1 of the circuit board 10.

### Connector Cover 30

The connector cover 30 is assembled on the connector 20 and is a waterproof member that prevents water from splashing on the mated portion of the connector 20 and the mating connector. As depicted in FIGS. 4, 5, 6 and 7, the connector cover 30 includes a back wall 31, a waterproof wall 32, a holder engaging portion 34, and two temporary fixing portions 38.

As depicted in FIGS. 5 and 7, the back wall 31 includes a first back wall 31A and a block-shaped connector insertion portion 31B that extends from the first back wall 31A. The back wall 31 further includes a connector entry hole 31C that extends through the first back wall 31A and the connector insertion portion 31B and allows the mating connector to be inserted.

As depicted in FIGS. 5 and 7, the waterproof wall 32 is a U-shaped wall that is erected from the first back wall 31A and surrounds the connector insertion portion 31B. As depicted in FIG. 5, the waterproof wall 32 includes a mating groove 33 on an outer surface thereof. The mating groove 33 is a groove that extends along the entire length of the waterproof wall 32.

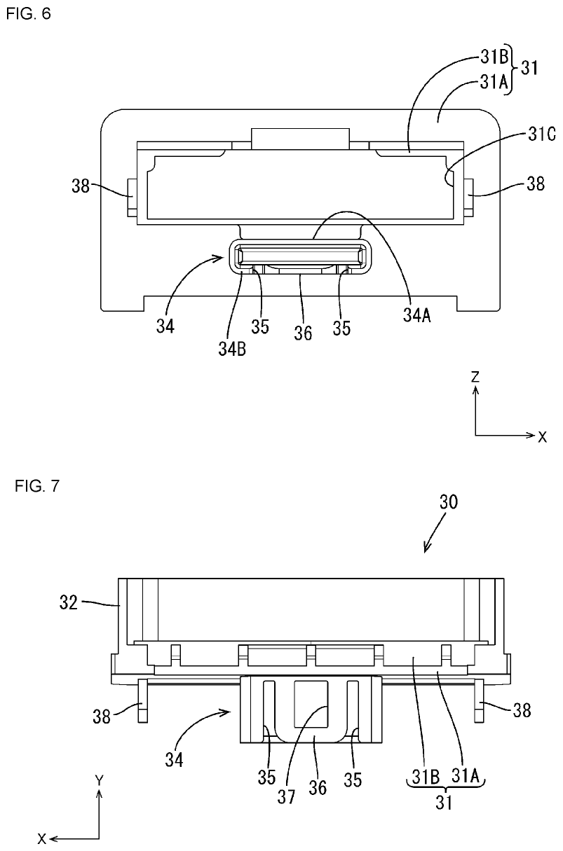

As depicted in FIGS. 5, 6, and 7, the holder engaging portion 34 is in the shape of a rectangular tube that extends from the first back wall 31A in the opposite direction to the waterproof wall 32. As depicted in FIG. 6, the holder engaging portion 34 includes a first parallel wall 34A and a second parallel wall 34B that are parallel to each other. As depicted in FIGS. 6 and 7, the second parallel wall 34B is provided with two slits 35 that are parallel to each other, with a part between the two slits 35 forming a first flexible piece 36 that is capable of bending with a part connected to the back wall 31 as a base end. This first flexible piece 36 includes an engagement hole 37.

As depicted in FIGS. 4, 6, and 7, each of the two temporary fixing portions 38 is a plate piece that protrudes from the back wall 31 in the opposite direction to the waterproof wall 32. As depicted in FIG. 6, the two temporary fixing portions 38 are disposed on both sides of the connector entry hole 31C.

### Capacitors 40

As examples, the capacitors 40 are electric double-layer capacitors, lithium ion capacitors, or the like, and each include a cylindrical capacitor main body 41 and two lead terminals 42 that extend from the capacitor main body 41.

### Holder 50

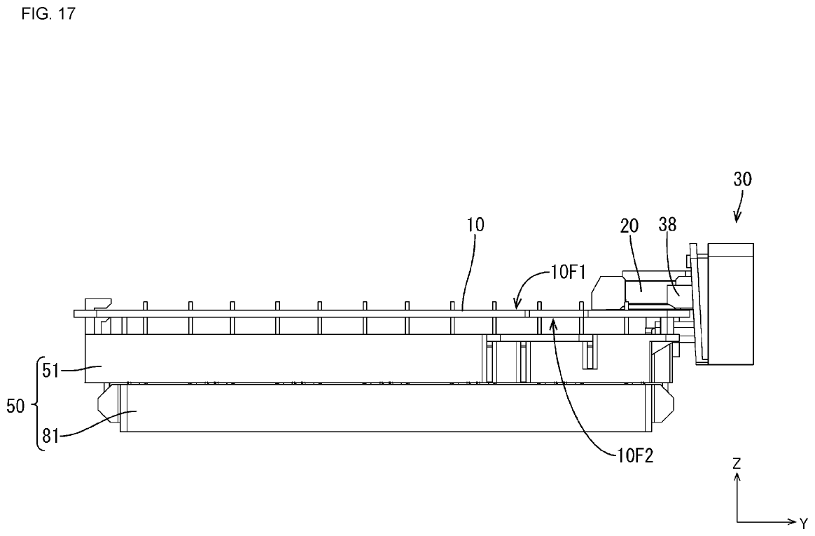

The holder 50 is made of synthetic resin, and, as depicted in FIGS. 2 and 17, is provided with the first holder 51 that is disposed on the holder disposing surface 10F2 of the circuit board 10 and a second holder 81 that is assembled on the first holder 51.

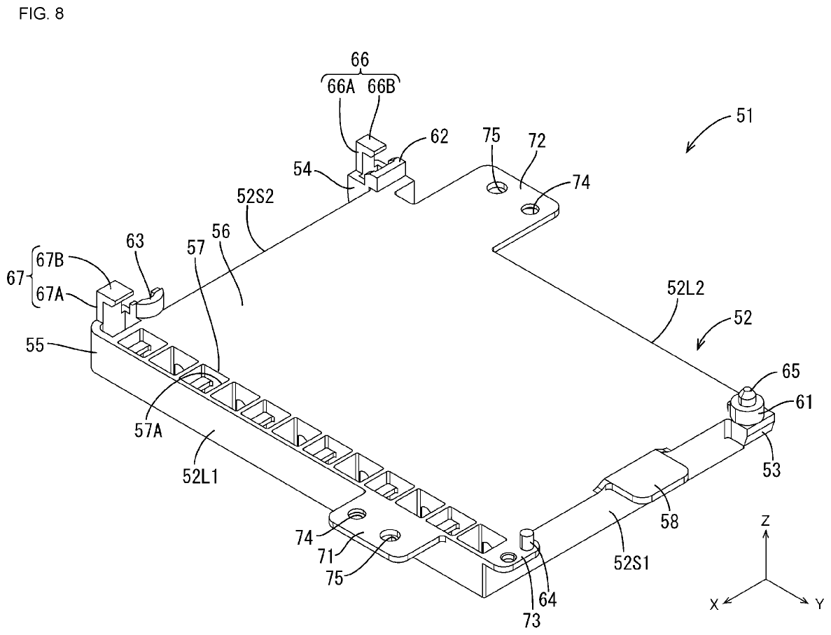

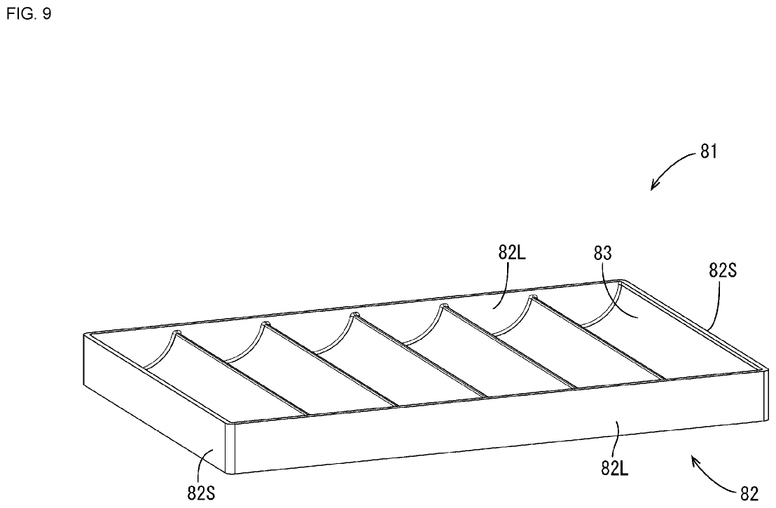

As depicted in FIG. 8, the first holder 51 includes a capacitor holding wall 56 in the form of a rectangular plate, a first frame 52 (one example of a “holder main body”) that extends from peripheral edges of the capacitor holding wall 56, and a lead insertion portion 57.

The first frame 52 is in the overall shape of a rectangular frame that is one size smaller than the circuit board 10, and includes a first long wall 52L1 and a second long wall 52L2 that are parallel to each other, a first short wall 52S1 and a second short wall 52S2 that connect ends of the first long wall 52L1 and the second long wall 52L2, a first support protrusion 53 that protrudes from the first short wall 52S1, and a second support protrusion 54 and a third support protrusion 55 that protrude from the second short wall 52S2.

The lead insertion portion 57 is disposed inside the first frame 52 and includes a plurality of lead insertion holes 57A through which the lead terminals 42 can be inserted.

The first holder 51 has a locking receiver portion 58 that engages the holder engaging portion 34 of the connector cover 30. As depicted in FIGS. 5 and 8, the locking receiver portion 58 is shaped as a plate-like piece that extends outward from the first short wall 52S1, and is provided with a locking receiver piece 58A disposed on the holder disposing surface 10F2 of the circuit board 10 and a first locking hook 58B that protrudes from the locking receiver piece 58A.

As depicted in FIG. 8, the first holder 51 includes a first support column 61 that extends from the first support protrusion 53 and a first boss 65 (an example of a “boss”) that extends from the first support column 61. The first support column 61 is cylindrical in shape, extends from the first support protrusion 53 toward the circuit board 10, and contacts the holder disposing surface 10F2 of the circuit board 10. The first boss 65 is formed in a cylindrical shape with a smaller diameter than the first support column 61, extends from the first support column 61, and is inserted through the first boss hole 16.

As depicted in FIG. 8, the first holder 51 includes a second support column 62 that extends from the second support protrusion 54 and a third support column 63 disposed adjacent to the third support protrusion 55. The second support column 62 is formed as a U-shaped plate, extends from the first support protrusion 53 toward the circuit board 10, and contacts the holder disposing surface 10F2 of the circuit board 10. The third support column 63 is shaped as a half pipe, has one end connected to the outer surface of the second short wall 52S2, and another end that contacts the holder disposing surface 10F2 of the circuit board 10.

As depicted in FIG. 8, the first holder 51 includes a first temporary locking portion 66 (or “temporary locking portion”, one example of “one of the temporary locking portions”) and a second temporary locking portion 67 (or “temporary locking portion”, one example of “another of the temporary locking portions”). The first temporary locking portion 66 is shaped as an L-shaped plate, and includes a plate-shaped first temporary locking piece 66A that extends from the second support protrusion 54 and a temporary holding plate 66B (one example of a “temporary holding portion”) that extends from the front end of the first temporary locking piece 66A. The second temporary holding portion 67 is formed as an L-shaped plate, and includes a plate-shaped second temporary locking piece 67A that extends from the third support protrusion 55 and a second temporary fixing plate 67B (one example of a “temporary fixing plate) that extends from the front end of the second temporary locking piece 67A. As depicted in FIG. 4, the first temporary locking piece 66A is received by the first temporary locking recess 12 and the second temporary locking piece 67A is received by the second temporary locking recess 13. The width W3 of the first temporary locking piece 66A defined by the distance between both side edges of the first temporary locking piece 66A is smaller than the width W4 of the second temporary locking piece 67A defined by the distance between both side edges of the second temporary locking piece 67A.

As depicted in FIG. 8, the first holder 51 includes a plate-like first mounting portion 71, a second mounting portion 72, and a third mounting portion 73. The first mounting portion 71 extends outward from the first long wall 52L1. The second mounting portion 72 extends outward from the second long wall 52L2. The first mounting portion 71 and the second mounting portion 72 each have one third boss hole 74 and one second screw insertion hole 75. The third mounting portion 73 extends outward from the first short wall 52S1. The third mounting portion 73 is provided with a fourth support column 64. The fourth support column 64 is cylindrical in shape, extends from the third mounting portion 73 toward the circuit board 10, and contacts the holder disposing surface 10F2 of the circuit board 10.

As depicted in FIG. 9, the second holder 81 includes a second frame 82 and a plurality of capacitor holding portions 83. The second frame 82 is formed in the shape of a rectangular frame with the same outer shape as the first frame 52, and includes two third long walls 82L that are parallel to each other and two third short walls 82S that connect the ends of the two third long walls 82L.

Each of the plurality of capacitor holding portions 83 is shaped as a half pipe. The plurality of capacitor holding portions 83 are disposed side by side inside the second frame 82.

When the second holder 81 is assembled on the first holder 51, one capacitor body 41 becomes held between the capacitor holding wall 56 and each capacitor holding portion 83. The lead terminals 42 of each capacitor 40 held by the holder 50 are inserted through the lead insertion holes 57A and the through-holes 11 and are soldered to the conductive paths on the circuit board 10.

### Outer Case 100

The outer case 100 is a shield case made of metal and includes a first outer case 101 and a second outer case 121.

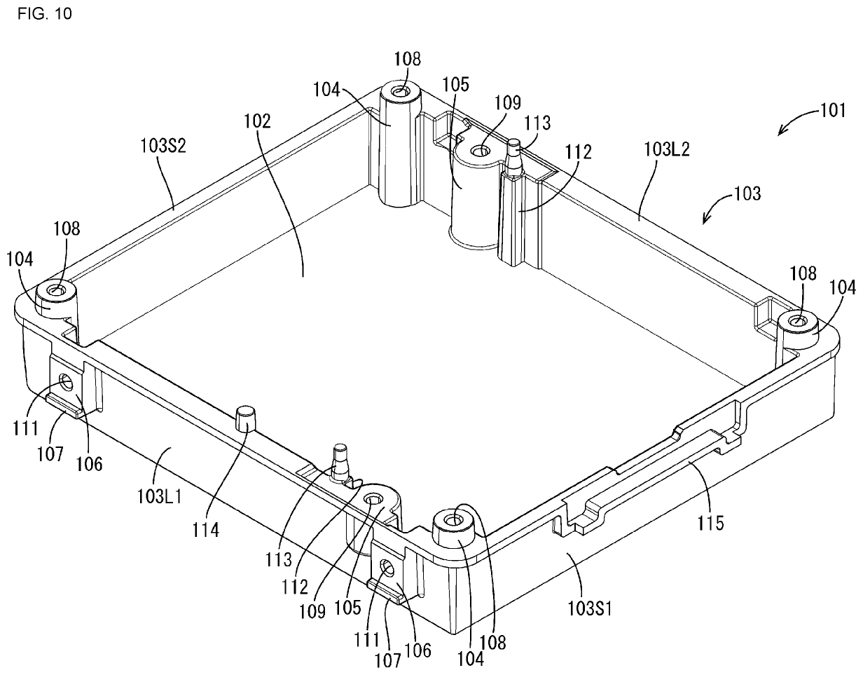

As depicted in FIG. 10, the first outer case 101 is a tray-shaped member capable of internally housing the holder 50, and includes a rectangular plate-shaped bottom wall 102 and a first peripheral wall 103 that extends from peripheral edges of the bottom wall 102. The first peripheral wall 103 includes a fourth long wall 103L1 and a fifth long wall 103L2 that extend from the two long sides of the bottom wall 102, and a fourth short wall 103S1 and a fifth short wall 103S2 that extend from the two short sides of the bottom wall 102.

The first outer case 101 is provided with four board fixing portions 104 for fixing the circuit board 10, two holder fixing portions 105 for fixing the holder 50, and four pedestals 106 and four case supports 107 for fixing the second outer case 121. Each of the four board fixing portions 104 is cylindrical and includes a first screw hole 108. The four board fixing portions 104 are disposed at the four corners of the first outer case 101. One end of each board fixing portion 104 protrudes from the first peripheral wall 103 in the opposite direction to the bottom wall 102 and contacts the holder disposing surface 10F2 of the circuit board 10.

One out of the two holder fixing portions 105 is disposed on an inner surface of the fourth long wall 103L1, and the other holder fixing portion 105 is disposed on the inner surface of the fifth long wall 103L2. Each holder fixing portion 105 is semi-cylindrical in shape and has a second screw hole 109.

Two out of the four pedestals 106 are disposed on the outer surface of the fourth long wall 103L1 and the other two pedestals 106 are disposed on the outer surface of the fifth long wall 103L2. Each pedestal 106 is block-shaped and has a third screw hole 111. The four case supports 107 are all bar-like in shape and protrude from bottom wall 102 side-edges of the four pedestals 106.

The first outer case 101 includes two fourth support protrusions 112 in the form of polygon-shaped columns and two second bosses 113 in the form of columns. One fourth support protrusion 112 is disposed adjacent to the holder fixing portion 105 on the inner surface of the fourth long wall 103L1, and the other fourth support protrusion 112 is disposed adjacent to the holder fixing portion 105 on the inner surface of the fifth long wall 103L2. The two second bosses 113 protrude from the two fourth support protrusions 112 and are inserted into the second boss holes 17.

The first outer case 101 includes a columnar fifth support column 114. The fifth support column 114 protrudes from the fourth long wall 103L1 in the opposite direction to the bottom wall 102 and contacts the holder disposing surface 10F2 of the circuit board 10.

The first outer case 101 has a support rib 115 formed in a bar-like shape that supports the connector cover 30. The support rib 115 is disposed on the outer surface of the fourth short wall 103S1 and supports the first back wall 31A and the waterproof wall 32.

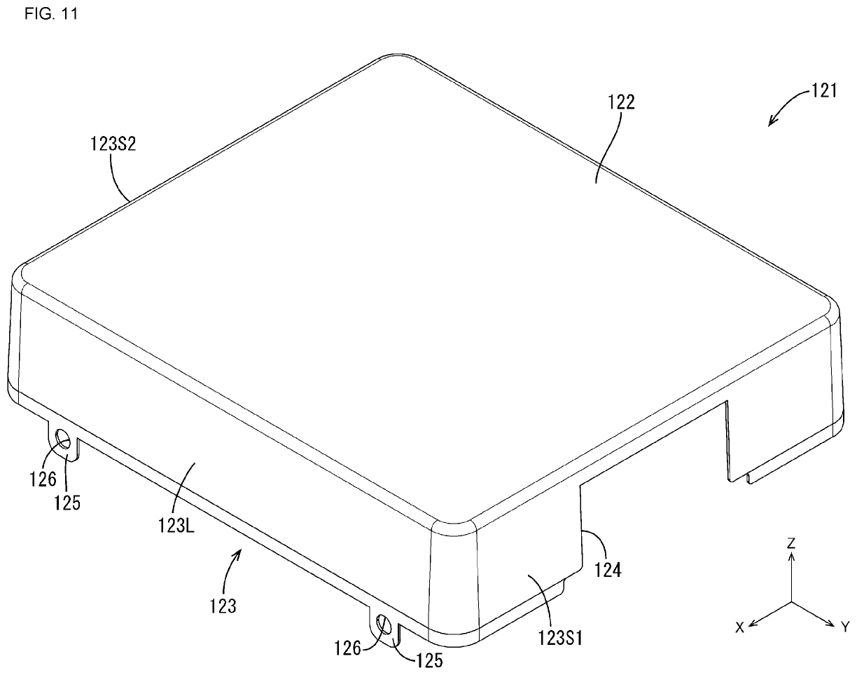

The second outer case 121 is a member that covers the first outer case 101 and the circuit board 10, and as depicted in FIG. 11, includes a top wall 122 in the form of a rectangular plate and a second peripheral wall 123 that extends from peripheral edges of the top wall 122. The second peripheral wall 123 includes sixth long walls 123L that extend from both long sides of the top wall 122, and a sixth short wall 123S1 and a seventh short wall 123S2 that extend from the two short sides of the top wall 122.

The sixth short wall 123S1 includes a cover recess 124 that internal receives the connector cover 30.

The second outer case 121 includes a plurality of plate-shaped fixing pieces 125. Two fixing pieces 125 extend from each of the two sixth long walls 123L. Each fixing piece 125 is disposed at a position corresponding to each pedestal 106 of the first outer case 101 and has a third screw insertion hole 126.

### Assembly of Electronic Device 1

Next, one example of an assembly procedure for the electronic device 1 will be described.

First, the connector 20 is fixed to the circuit board 10 by reflow soldering.

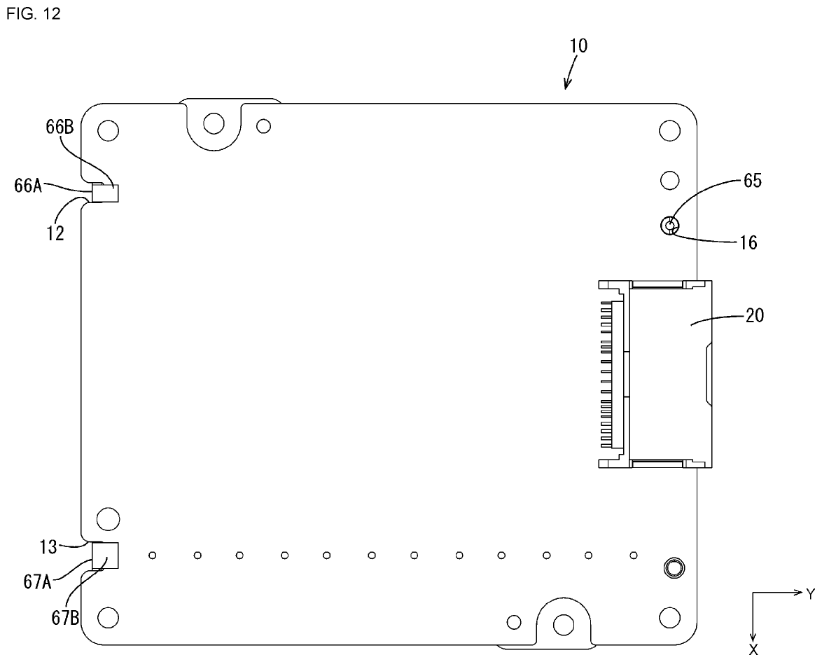

Next, the circuit board 10 is assembled on the first holder 51 as depicted in FIGS. 12, 13, and 14. First, the first temporary locking piece 66A advances into the first temporary locking recess 12, and the second temporary locking piece 67A advances into the second temporary locking recess 13, which locks the second end of the circuit board 10 on the first holder 51. Since the width W1 of the first temporary locking recess 12 is larger than the width W3 of the first temporary locking piece 66A but smaller than the width W4 of the second temporary locking piece 67A, the first temporary locking recess 12 can receive the first temporary locking piece 66A but is not able to receive the second temporary locking piece 67A (see FIG. 4). With this this configuration, the circuit board 10 is prevented from being fixed to the first holder 51 in the wrong orientation.

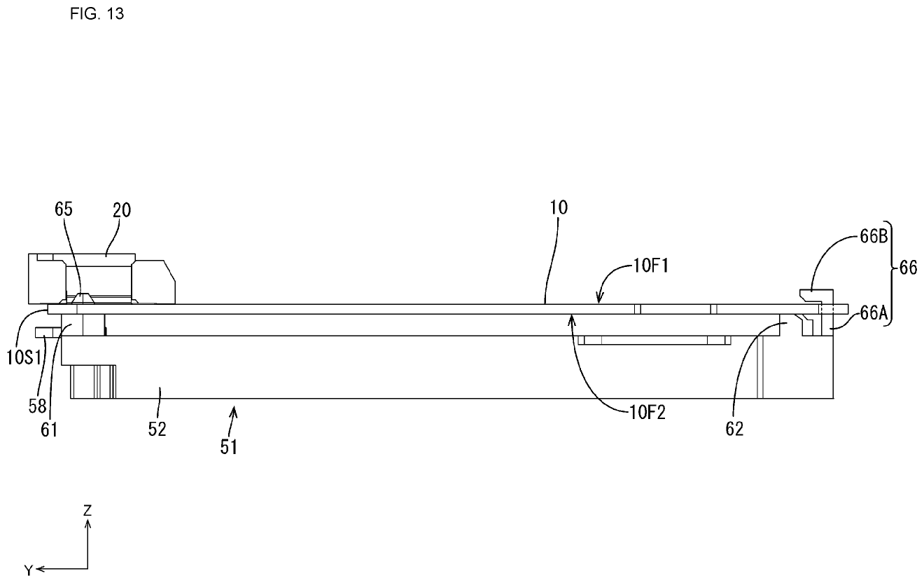

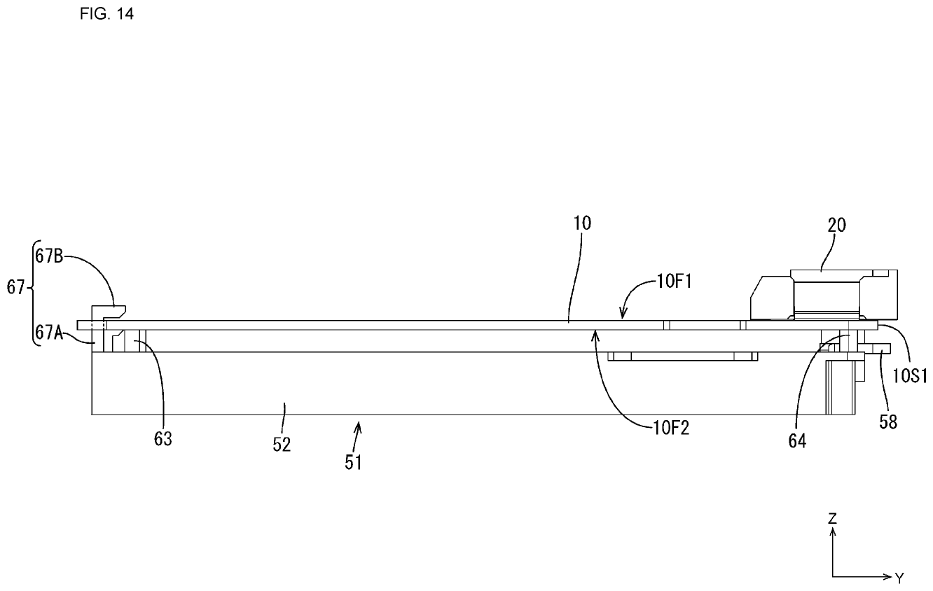

Next, the first boss 65 is inserted through the first boss hole 16 to position the first end of the circuit board 10 in the first holder 51. As depicted in FIGS. 13 and 14, the first frame 52 and the locking receiver portion 58 are disposed on the holder disposing surface 10F2 of the circuit board 10, and the first support column 61, the second support column 62, the third support column 63 and the fourth support column 64 contact the holder disposing surface 10F2 of the circuit board 10 to support the circuit board 10. The first temporary holding plate 66B and the second temporary holding plate 67B are disposed on the connector disposing surface 10F1 of the circuit board 10 and restrict movement of the second end of the circuit board 10 away from the first frame 52.

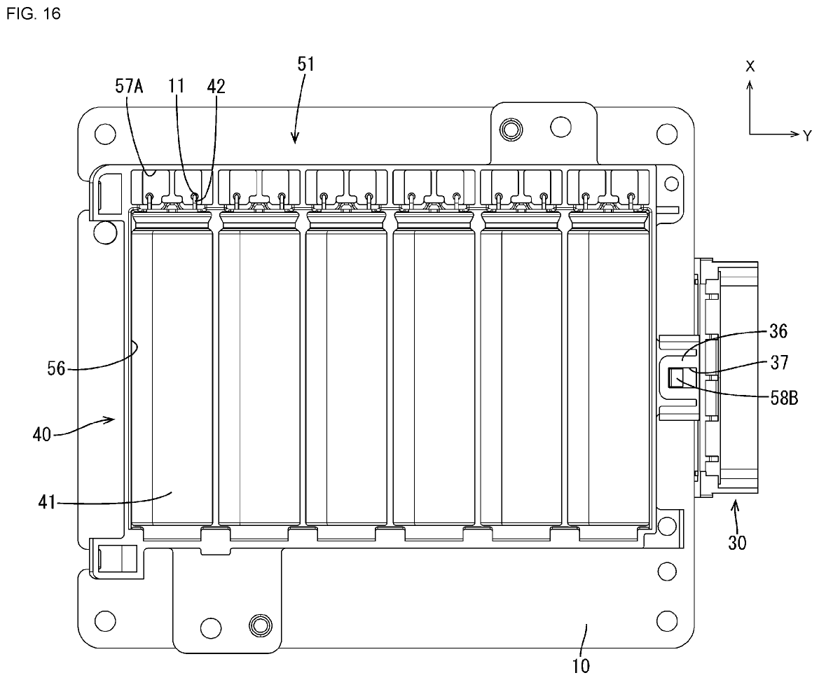

Next, the connector cover 30 is assembled on the first holder 51 on which the circuit board 10 has been assembled. As depicted in FIG. 5, the holder engaging portion 34 is disposed on the holder disposing surface 10F2 of the circuit board 10, and has the lock receiving piece 58A is inserted thereinto. The first flexible piece 36 rides up the first locking hook 58B and bends outward and once the first locking hook 58B enters the locking hole 37, the first flexible piece 36 is elastically restored and the first locking hook 58B becomes engaged on the edge of the locking hole 37 (see also FIG. 16). Also, as depicted in FIG. 4, the two temporary fixing portions 38 are disposed on the connector disposing surface 10F1 of the circuit board 10 and restrict the movement of the circuit board 10 in a direction away from the first frame 52. As a result, the circuit board 10 is temporarily fixed by the first holder 51 and the connector cover 30. Due to the first temporary locking piece 66A entering the first temporary locking recess 12, the second temporary locking piece 67A entering the second temporary locking recess 13, the two temporary fixing portions 38 being disposed on both sides of the connector 20 and the first boss 65 entering the first boss hole 16, positional displacement of the circuit board 10 is restricted.

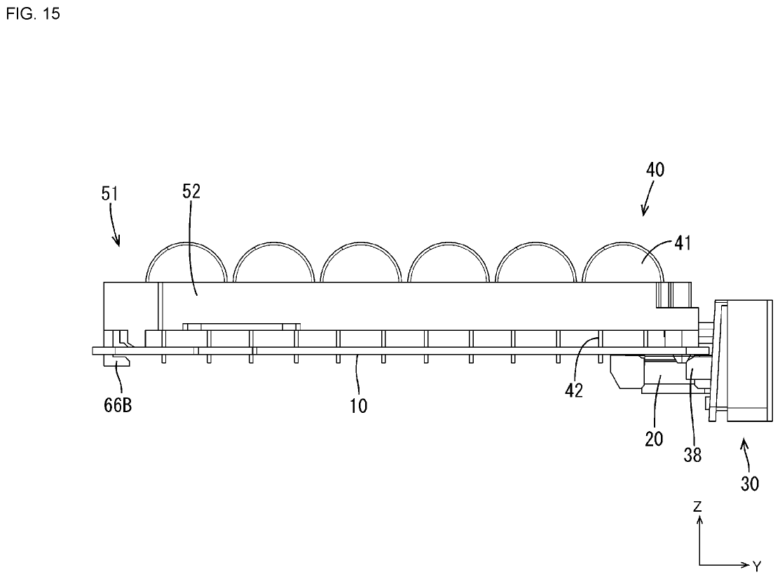

Next, the capacitors 40 are attached to the first holder 51. First, as depicted in FIGS. 15 and 16, an assembly composed of the circuit board 10, the first holder 51, and the connector cover 30 is arranged in a posture (the posture depicted in FIG. 15) where the circuit board 10 is below the first holder 51. Next, the capacitors 40 are set from above in the first holder 51. The lead terminals 42 are inserted through the corresponding lead insertion holes 57A and through-holes 11. As described above, since the circuit board 10 is temporarily fixed by the first holder 51 and the connector cover 30, movement of the circuit board 10 in the direction away from the first frame 52 is restricted by the first temporary holding plate 66B, the second temporary holding plate 67B, and the temporary fixing portions 38. This means that the circuit board 10 is prevented from falling out of the first holder 51 during the work of mounting the capacitors 40, which enables the task of mounting the capacitors 40 to be performed smoothly.

Next, the second holder 81 is assembled on the first holder 51 as depicted in FIG. 17. The capacitor body 41 is held by being sandwiched between the first holder 51 and the second holder 81.

Next, the lead terminals 42 of the capacitor 40 are connected by soldering to the conductive paths on the circuit board 10.

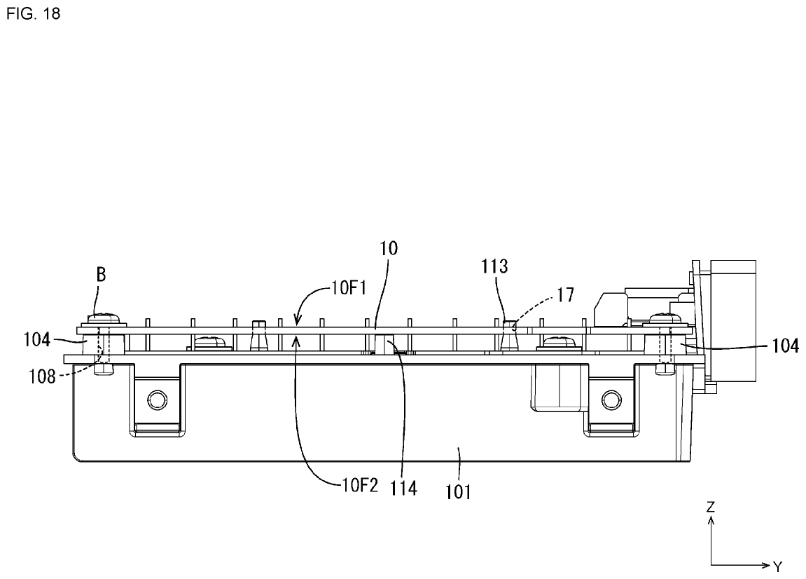

Next, as depicted in FIGS. 18, 19, and 20, the circuit board 10 and the holder 50 are assembled to the first outer case 101. The holder 50 becomes housed inside the first outer case 101. The circuit board 10 is positioned with respect to the first outer case 101 by inserting the second boss 113 into the second boss hole 17. The four board fixing portions 104 and the fifth support column 114 contact the holder disposing surface 10F2 of the circuit board 10 to support the circuit board 10. The holder fixing portions 105 contact the first mounting portions 71.

In this state, the four screws B are inserted into the first screw insertion holes 15 and screwed into the four board fixing portions 104, thereby fixing the circuit board 10 to the first outer case 101. The holder 50 is fixed to the first outer case 101 by inserting the two other screws B through the second screw insertion holes 75 and screwing these screws B into the holder fixing portions 105. In this way, the circuit board 10 and the holder 50 are not collectively screwed to the first outer case 101, and instead the circuit board 10 and the holder 50 are separately screwed to the first outer case 101. By doing so, since the circuit board 10 and the holder 50 are firmly fixed to the first outer case 101, positional displacement of the circuit board 10 and the holder 50 with respect to the first outer case 101 is avoided, which prevents loads (forces) from being applied to the soldered parts of the lead terminals 42 and the circuit board 10.

Next, as depicted in FIG. 1, the second outer case 121 is assembled on the first outer case 101. The second outer case 121 is placed on the first outer case 101 so that the top wall 122 covers the circuit board 10. A peripheral portion of the cover recess 124 fits inside the mating groove 33, and the connector cover 30 is disposed so that most of the waterproof wall 32 protrudes outside the outer case 100. The fixing pieces 125 are disposed along the pedestals 106 and are supported by the case supports 107. The four screws B are inserted through the third screw insertion holes 126 and screwed into the respective pedestals 106.

Through the procedure described above, assembly of the electronic device 1 is completed.

### Effects

As described above, according to the present embodiment, the electronic device 1 includes the circuit board 10, which has the holder disposing surface 10F2 and the connector disposing surface 10F1 on the opposite side to the holder disposing surface 10F2, the holder 50 that holds the capacitors 40, and the connector cover 30 that is assembled on the holder 50 and disposed at the first end of the circuit board 10. The connector cover 30 includes the holder engaging portion 34 that is disposed on the holder disposing surface 10F2 of the circuit board 10 and engages the holder 50 and the temporary fixing portions 38 that are disposed on the connector disposing surface 10F1 of the circuit board 10. The holder 50 includes the first frame 52 disposed on the holder disposing surface 10F2 of the circuit board 10 and the first temporary locking portion 66 and the second temporary locking portion 67 that extend from the first frame 52 and are disposed at the second end that is opposite the first end of the circuit board 10. The first temporary locking portion 66 and the second temporary locking portion 67 are provided with the first temporary holding plate 66B and the second temporary holding plate 67B that are disposed on the connector disposing surface 10F1 of the circuit board 10.

According to the above configuration, during assembly of the electronic device 1, the second end of the circuit board 10 is held between the first frame 52 and the first temporary holding plate 66B and the second temporary holding plate 67B. The holder 50 is engaged by the holder engaging portion 34 of the connector cover 30, and the first end of the circuit board 10 becomes held between the holder engaging portion 34 and the temporary fixing portions 38. By doing so, the circuit board 10 can easily be temporarily fixed to the holder 50 without applying stress to the circuit board 10.

In addition, the circuit board 10 includes the first temporary locking recess 12 that is disposed at the second end and receives the first temporary locking portion 66 and the second temporary locking recess 13 that is also disposed at the second end and receives the second temporary locking portion 67.

With the above configuration, positional displacement between the circuit board 10 and the holder 50 can be suppressed, which enables assembly of the electronic device 1 to be performed smoothly.

The first holder 51 includes the first temporary locking portion 66 and the second temporary locking portion 67 that have different widths, and the circuit board 10 has the first temporary locking recess 12 and the second temporary locking recess 13 for receiving the first temporary locking portion 66 and the second temporary locking portion 67, respectively. The first temporary locking recess 12 has the width W1 that is capable of receiving the first temporary locking portion 66 but incapable of receiving the second temporary locking portion 67.

With this configuration, a situation where the circuit board 10 is fixed to the first holder 51 in the wrong orientation is avoided.

Also, the circuit board 10 includes the first boss hole 16 that is disposed at the first end, and the holder 50 has the first boss 65 that is inserted through the first boss hole 16. According to this configuration, after the second end of the circuit board 10 has been held between the first frame 52 and the first temporary holding plate 66B and second temporary holding plate 67B, it is possible to prevent the first end of the circuit board 10 from becoming positionally displaced from the holder 50 until the connector cover 30 is assembled, which makes it possible to assemble the electronic device 1 smoothly.

The electronic device 1 includes the connector 20 that is attached to the circuit board 10, and the circuit board 10 is temporarily fixed by the connector cover 30 that covers at least part of the connector 20.

With this configuration, the connector cover 30 also serves to temporarily fix the circuit board 10, which can suppress an increase in the number of components.

Also, the connector cover 30 has two temporary fixing portions 38 disposed on both sides of the connector 20. With this configuration, positional displacements between the circuit board 10 and the connector cover 30 can be suppressed, which enables assembly of the electronic device 1 to be performed smoothly.

The electronic device 1 includes an outer case 100 that covers the circuit board 10 and the holder 50. The outer case 100 includes the board fixing portions 104, to which only the circuit board 10 is fixed, and the holder fixing portions 105, to which only the holder 50 is fixed.

According to the above configuration, the circuit board 10 and the holder 50 are separately fixed to the outer case 100. With this configuration, the circuit board 10 and the holder 50 are firmly fixed to the outer case 100 compared to a configuration where the circuit board 10 and the holder 50 are collectively fixed to the outer case 100. Positional displacements of the circuit board 10 and the holder 50 with respect to the first outer case 101 are avoided, which avoids a situation where a load is applied to a soldered part of the lead terminals 42 and the circuit board 10.

### Other Embodiments

Although the outer case 100 is a shield case made of metal in the above embodiment, the outer case may be made of resin and omit the function as a shield.

Although the fixing member is the connector cover 30 in the above embodiment, the fixing member may be a member with a function aside from a function of covering the connector, or may be a member with only a function of temporarily fixing the circuit board.

1. An electronic device comprising:
a circuit board including a first surface and a second surface on an opposite side to the first surface;
a holder for holding a power storage element; and
a fixing member that is assembled on the holder and is disposed at a first end of the circuit board,
wherein the fixing member includes a holder engaging portion, which is disposed on the first surface of the circuit board and engages the holder, and at least one temporary fixing portion, which is disposed on the second surface of the circuit board, and
the holder includes a holder main body that is disposed on the first surface of the circuit board and at least one temporary locking portion that extends from the holder main body and is disposed at a second end on an opposite side to the first end of the circuit board, wherein each temporary locking portion includes a temporary holding portion disposed on the second surface of the circuit board.

2. The electronic device according to claim 1, wherein the circuit board includes at least one temporary locking recess that is disposed at the second end and receives the at least one temporary locking portion.

3. The electronic device according to claim 2, wherein the holder includes a plurality of the temporary locking portions of different widths and the circuit board includes a plurality of the temporary locking recesses for receiving the plurality of temporary locking portions, and
one temporary locking recess out of the plurality of temporary locking recesses has a width that is capable of receiving one of the temporary locking portions but is incapable of receiving another of the temporary locking portions.

4. The electronic device according to claim 1,
wherein the circuit board includes a boss hole disposed at the first end, and
the holder includes a boss that is inserted through the boss hole.

5. The electronic device according to claim 1,
further including a connector attached to the circuit board,
wherein the fixing member is a connector cover that covers at least part of the connector.

6. The electronic device according to claim 5, wherein the connector cover includes two temporary fixing portions disposed on both sides of the connector.

7. The electronic device according to claim 1,
further including an outer case for covering the circuit board and the holder,
wherein the outer case includes a board fixing portion to which only the circuit board is fixed and a holder fixing portion to which only the holder is fixed.

8. The electronic device according to claim 2,
wherein the circuit board includes a boss hole disposed at the first end, and
the holder includes a boss that is inserted through the boss hole.

9. The electronic device according to claim 3,
wherein the circuit board includes a boss hole disposed at the first end, and
the holder includes a boss that is inserted through the boss hole.

10. The electronic device according to claim 2,
further including a connector attached to the circuit board,
wherein the fixing member is a connector cover that covers at least part of the connector.

11. The electronic device according to claim 3,
further including a connector attached to the circuit board,
wherein the fixing member is a connector cover that covers at least part of the connector.

12. The electronic device according to claim 4,
further including a connector attached to the circuit board,
wherein the fixing member is a connector cover that covers at least part of the connector.

13. The electronic device according to claim 2,
further including an outer case for covering the circuit board and the holder,
wherein the outer case includes a board fixing portion to which only the circuit board is fixed and a holder fixing portion to which only the holder is fixed.

14. The electronic device according to claim 3,
further including an outer case for covering the circuit board and the holder,
wherein the outer case includes a board fixing portion to which only the circuit board is fixed and a holder fixing portion to which only the holder is fixed.

15. The electronic device according to claim 4,
further including an outer case for covering the circuit board and the holder,
wherein the outer case includes a board fixing portion to which only the circuit board is fixed and a holder fixing portion to which only the holder is fixed.

16. The electronic device according to claim 5,
further including an outer case for covering the circuit board and the holder,
wherein the outer case includes a board fixing portion to which only the circuit board is fixed and a holder fixing portion to which only the holder is fixed.

17. The electronic device according to claim 6,
further including an outer case for covering the circuit board and the holder,
wherein the outer case includes a board fixing portion to which only the circuit board is fixed and a holder fixing portion to which only the holder is fixed.
